(19) United States
(12) Patent Application Publication
(10) Pub. No.: US 2009/0289727 A1
(43) Pub. Date: Nov. 26, 2009

(54) OSCILLATOR FOR GENERATING DIFFERENT OSCILLATIONS

(75) Inventor: Samir El Rai, Colorado Springs, CO (US)

Correspondence Address: Muncy, Geissler, Olds & Lowe, PLLC, P.O. BOX 1364, FAIRFAX, VA, 22038-1364, US

(73) Assignee: ATMEL DUISBURG GmbH, Duisburg (DE)

(21) Appl. No.: 12/124,208

(22) Filed: May 21, 2008

Related U.S. Application Data
(60) Provisional application No. 60/941,623, filed on Jun. 1, 2007.

(30) Foreign Application Priority Data
May 21, 2007 (DE) 10 2007 023 795.4

(51) Int. Cl. H03K 3/03

(52) U.S. Cl. 331/46

(57) ABSTRACT

An oscillator is provided that includes a first oscillation generating device for generating an oscillation in response to an excitation signal, whereby the first oscillation generating device has a first terminal and a second terminal; a second oscillation generating device for generating an oscillation in response to an excitation signal, whereby the second oscillation generating device has a third terminal and a fourth terminal; an excitation device, which is formed in a first mode to apply an excitation signal between the first and second terminal of the first oscillation generating device, and in the first mode to apply the excitation signal between the third terminal and the fourth terminal of the second oscillation generating device to obtain a first oscillation with a first characteristic value, and in a second mode to apply an excitation signal between the first terminal of the first oscillation generating device and the third terminal of the second oscillation generating device and in the second mode to apply the excitation signal between the second terminal of the first oscillation generating device and the fourth terminal of the second oscillation generating device to obtain a second oscillation with a second characteristic value.

This nonprovisional application claims priority to German Patent Application No. DE 10 2007 023 795.4, which was filed in Germany on May 21, 2007, and to U.S. Provisional Application No. 60/941,623, which was filed on Jun. 1, 2007, and which are both herein incorporated by reference.

### BACKGROUND OF THE INVENTION

1. Field of the Invention

The present invention relates to the field of oscillation generation.

2. Description of the Background Art

Dual- or multiband transceivers are often needed in modern communications engineering systems for transmitting or receiving signals that occupy different frequency ranges. For this reason, all circuits in such systems, particularly the oscillator circuits, should be designed for the particular frequency range, to meet the particular system requirements, either broad-band or narrow-band oscillator circuits being used at present. An example of a voltage-controlled oscillator is disclosed in U.S. Pat. No. 6,943,636 B2.

Broad-band oscillator circuits in fact enable the processing of two or more bands with use of the same circuit. They are not always realizable for the desired frequency bands, however. Narrow-band oscillator circuits, in contrast, can be realized as tunable, switchable circuits. Circuits that need to exhibit a high performance are realized in duplicate, if the frequency bands are to be spaced far from one another.

In this regard, voltage-controlled oscillators in the aforementioned systems can be cited in which the reduced quality and higher noise must be accepted in favor of a greater tuning range. If the frequency bands are far from one another, the two-circuit concept is generally used.

FIG. 8 shows an oscillator circuit with a resonant circuit 801 (tank) and an amplifier 803 connected to the tank. Tank 801 is provided to generate an oscillation in response to an excitation signal supplied by amplifier 803. Tank 801 comprises two inductors with the respective value L1, whose ohmic resistance has the value R1 in each case. Furthermore, tank 801 comprises several capacitor networks each with two capacitors, each of which are connected via a switch.

The oscillation frequency that can be generated by the oscillator circuit in FIG. 8 is:

f=1/(2π\sqrt{LC}),

where L is the effective inductance of tank circuit 801 and C the capacitance of tank circuit 801.

A two-circuit concept is shown in FIGS. 9a and 9b, in which several tanks circuits 901, 903 and several amplifiers 905 and 907 are needed in each case. During operation, the circuit required in each case is turned on, whereas the other circuit remains turned off. Examples of two-circuit concepts are disclosed in U.S. Pat. Nos. 5,856,763 and 5,748,049.

### SUMMARY OF THE INVENTION

It is therefore an object of the present invention to provide for the most efficient concept possible for realizing oscillators for generating different oscillations.

The present invention is based on the realization that different oscillations with, for example, different oscillation frequencies can be realized by using two or more oscillation generating devices, for example, oscillation circuits (tank circuits), and an excitation device, which can have one or more amplifiers. The excitation device can operate, for example, in two different modes, whereby in a first mode the first and second oscillation generating device are excited, and whereby in the first mode an excitation signal required for oscillation generation is applied at the respective inputs of the first and second oscillation generating device. In a second mode, an excitation signal is applied, for example, between a first input of a first oscillation generating device and a second input of a second oscillation generating device and between a second input of the first oscillation generating device and a second input of the second oscillation generating device.

According to the invention, a second resonant circuit can be used to achieve a higher stability of the oscillations and/or higher oscillation energies. According to the invention, therefore, voltage-controlled oscillators with two or more bands can be realized, which have an improved performance compared with the prior art, because the quality is higher due to the improved ratio of oscillation energy to noise energy. Furthermore, the stability is increased.

The invention provides for an oscillator with a first oscillation generating device for generating an oscillation in response to an excitation signal, whereby the first oscillation generating device has a first terminal and a second terminal, with a second oscillation generating device for generating an oscillation in response to an excitation signal, whereby the second oscillation generating device has a third terminal and a fourth terminal.

The oscillator has an excitation device, which is formed in a first mode to apply an excitation signal between the first and second terminal of the first oscillation generating device and between the third terminal and the fourth terminal of the second oscillation generating device, to obtain a first oscillation with a first characteristic value.

The excitation device is formed in a second mode to apply an excitation signal between the first terminal of the first oscillation generating device and the third terminal of the second oscillation generating device and between the second terminal of the first oscillation generating device and the fourth terminal of the second oscillation generating device, to obtain a second oscillation with a second characteristic value.

The excitation device is preferably formed in the first mode to apply no excitation signal between the first terminal and the third terminal, and whereby further the excitation device is formed advantageously in the second mode to apply no signal between the second terminal and the fourth terminal.

According to an embodiment, the first terminal of the first oscillation generating device is coupled to the third terminal of the second oscillation generating device via a capacitive or inductive network, whereby the second terminal of the first oscillation generating device is coupled to the fourth terminal of the second oscillation generating device via a capacitive or inductive network.

According to an embodiment, the excitation device comprises a first amplifier, which is connected between the first terminal and the second terminal of the first oscillation generating device, and a second amplifier, which is connected between the first terminal of the first oscillation generating device and the third terminal of the second oscillation generating device.

According to an embodiment, the excitation device comprises a third amplifier, which is connected between the third terminal and the fourth terminal of the second oscillation generating device, and a fourth amplifier, which is connected between the second terminal of the first oscillation generating device and the fourth terminal of the second oscillation generating device.

According to an embodiment, the first oscillation generating device and the second oscillation generating device each comprise an inductive network with switchable capacitors.

According to an embodiment, the first characteristic value and the second characteristic value are different.

According to an embodiment, the first characteristic value or the second characteristic value is an oscillation amplitude or an oscillation frequency.

According to an embodiment, the first oscillation generating device and the second oscillation generating device each have a conductive structure, connected to one another conductively via another conductive structure.

According to an embodiment, the first terminal and the second terminal of the first oscillation generating device are connected conductively via a conductive structure, whereby the third terminal and the fourth terminal of the second oscillation generating device are connected conductively via a conductive structure.

According to an embodiment, the first oscillation generating device and the second oscillation generating device each have a conductive structure, which is formed at least in part as a loop.

According to an embodiment, the first oscillation generating device and the second oscillation generating device each have a conductive structure, which overlap at least in part.

According to an embodiment, the oscillator is a reflection-type oscillator. In this case, for example, a noise of an oscillation generating device, e.g., a resonant circuit, is passed on to the excitation device, which amplifies a noise component at the desired oscillation frequency and applies it as an excitation signal at the oscillation generating device. The oscillator, therefore, is self-excited. According to another embodiment, the oscillator can be separate-excited, however.

The invention further provides for a use of an excitation device for oscillation generation, whereby the excitation device is formed in a first mode to apply an excitation signal between a first and second terminal of a first oscillation generating device and between a third and fourth terminal of a second oscillation generating device, to obtain a first oscillation with a first characteristic value, and whereby the excitation device is formed further in a second mode to apply an excitation signal between the first terminal of the first oscillation generating device and the third terminal of the second oscillation generating device and between the second terminal of the first oscillation generating device and the fourth terminal of the second oscillation generating device, to obtain a second oscillation with a second characteristic value.

The invention further provides for an oscillation generating method with the step of generating an oscillation by means of a first oscillation generating device in response to an excitation signal, whereby the first oscillation generating device has a first terminal and a second terminal, of generating an oscillation by means of a second oscillation generating device in response to an excitation signal, whereby the second oscillation generating device has a third terminal and a fourth terminal, of applying an excitation signal between the first and second terminal of the first oscillation generating device and between the third and fourth terminal of the second oscillation generating device, to obtain the first oscillation with a first characteristic value. Furthermore, a step occurs of the application of an excitation signal between the first terminal of the first oscillation generating device and the third terminal of the second oscillation generating device and between the second terminal of the first oscillation generating device and the fourth terminal of the second oscillation generating device, to obtain a second oscillation with a second characteristic value.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a block diagram of an oscillator according to an embodiment;

FIG. 2 shows a circuit diagram of an oscillator according to an embodiment;

FIGS. 3a and 3b show signal polarities in different modes of the oscillator circuit of FIG. 2;

FIG. 4 shows an oscillator according to an embodiment;

FIG. 5 shows an oscillator according to an embodiment; and

FIG. 6 shows an oscillator according to an embodiment;

FIG. 7 shows a receiver;

FIG. 8 shows an oscillator; and

FIG. 9 shows an oscillator.

### DETAILED DESCRIPTION

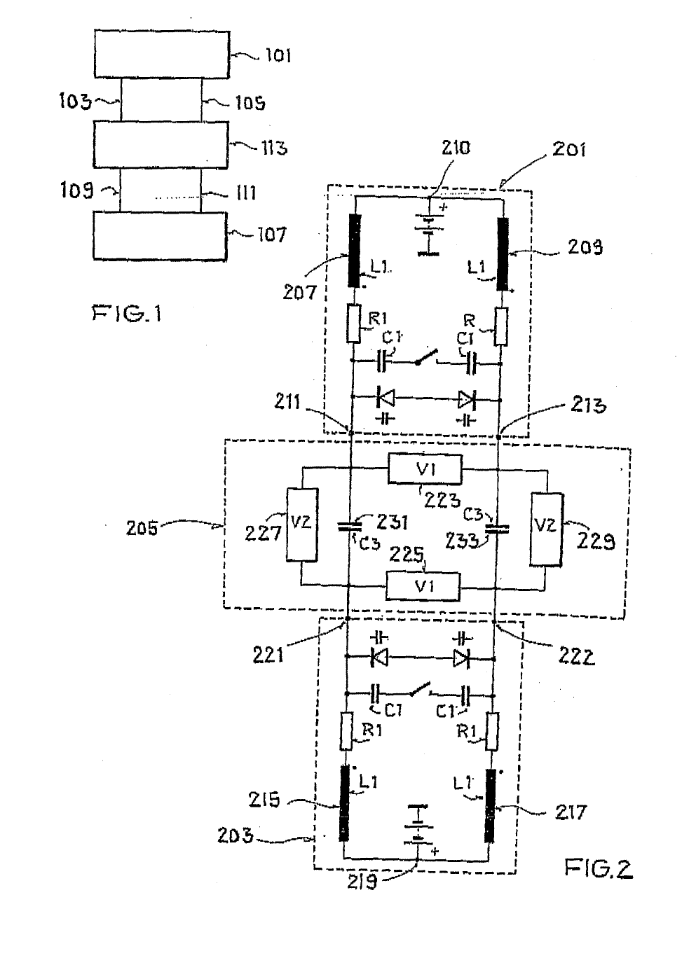

FIG. 1 shows an oscillator with a first oscillation generating device 101, which has a first terminal 103 and a second terminal 105. The oscillator comprises further a second oscillation generating device 107 with a third terminal 109 and a fourth terminal 111. The first oscillation generating device 101 and second oscillation generating device 107 are connected to an excitation device 113, which in a first mode applies an excitation signal between first terminal 103 and second terminal 105, in response to which first oscillation generating device 101 generates a first oscillation with a first characteristic value, for example, with a first frequency. Excitation device 113 is formed further in a second mode to apply an excitation signal, which can differ from the excitation signal applied in the first mode, between first terminal 103 of first oscillation generating device 101 and third terminal 109 of second oscillation generating device 107 or to apply it between terminal 105 of first oscillation generating device 101 and terminal 111 of second oscillation generating device 107.

Terminals 103 and 109, furthermore, can be connected to one another, for example, by means of a capacitor. Similarly, terminals 105 and 111 can be connected via a capacitor. Furthermore, in each case, a capacitor can be provided between terminals 103 and 105 or between terminals 109 and 111.

FIG. 2 shows an oscillator with a first oscillation generating device 201, a second oscillation generating device 203, and an excitation device 205, to which the first and second oscillation generating devices 201 and 203 are connected. The first oscillation generating device comprises two inductors 207 and 209, which are connected via a nodal point 210, at which, for example, a ground potential or a DC potential can be applied. Inductors 207 and 209 each have an inductance value L1 and an ohmic resistance value R1, which is inherent to the respective inductor. Inductors 207 and 209 can be, for example, subinductors (e.g., partial turns) of a common inductor, which are connected to one another via nodal point 211.

Inductor 207 is connected via a first terminal 211 and via a third terminal 213 to excitation device 205. Inductor 207 is connected, for example, directly to first terminal 211. Inductor 209 is connected, for example, directly to second terminal 213. Furthermore, a capacitive circuit comprising two capacitors switchable in the series via a switch is disposed between terminals 211 and 213. Furthermore, a diode circuit comprising two diodes connected in antiseries is disposed between terminals 211 and 213. The diodes can be, for example, identical diodes. Analogously, the capacitors can have identical capacitance values C1. The diodes can be analog and analog-tunable diodes, for example, varactor diodes.

The second oscillation generating device 203 preferably has a structure matching that of first oscillation generating device 201. Thus, second oscillation generating device 203 has two inductors 215 and 217, which are connected to one another via a nodal point 219. A ground potential or other DC potential, for example, can be applied at nodal point 219. Inductors 215 and 217 have, for example, identical inductance values L1. Moreover, inductors 215 and 217 can be notable for the identical values of the ohmic resistance R1. Inductors 215 and 217 are each connected via a third terminal 221 and a fourth terminal 222 of the second oscillation generating device. A capacitive circuit is provided between terminals 221 and 222; it has two capacitors connectable in series via a switch, each with, for example, an identical capacitance value C1. Moreover, a diode circuit comprising two diodes connected in antiseries is provided between terminals 221 and 222. Terminals 221 and 222 are also coupled to excitation device 205.

Alternatively, the inductors of the first oscillation generating device and the second oscillation generating device can be formed by a single inductor.

Excitation device 205 comprises a first amplifier 223, which is connected between first terminal 221 and second terminal 213 of first oscillation generating device 201. Excitation device 205 comprises further a second amplifier 225, which is connected between third terminal 221 of the second oscillation generating device and fourth terminal 222 of second oscillation generating device 203. Amplifiers 223 and 225 are preferably made identical.

Excitation device 205 comprises further a third amplifier 227, which is connected between first terminal 211 of the first oscillation generating device and third terminal 222 of second oscillation generating device 203. Excitation device 205 comprises further a fourth amplifier 229, which is connected between second terminal 213 of first oscillation generating device 201 and fourth terminal 222 of second oscillation generating device 203.

First terminal 211 of first oscillation generating device 201 is connected via a capacitor 231 to third terminal 221 of second oscillation generating device 203. Second terminal 213 of first oscillation generating device 201 is connected via another capacitor 233 to fourth terminal 222 of second oscillation generating device 203. Capacitors 231 and 233 have, for example, identical capacitance values C3. However, any capacitor or inductor networks, for example, LC networks, can be connected between terminals 211 and 221 or 213 and 222. In analogy to this, according to an embodiment, capacitive or inductive networks can also be disposed between terminals 211 and 213 or between terminals 221 and 222.

Excitation device 205 is provided to turn off amplifiers 227 and 229 (V2) and to turn on amplifiers 223 and 225 (V1) in a first mode. In this case, capacitors 231 and 233 (C3) are used for synchronizing the two oscillation generating devices 201 and 203 (oscillation circuits). A higher signal-to-noise or energy-to-noise ratio is obtained in this way. At the same time, the load-carrying capacity of the circuit and thereby the loaded quality are increased. Capacitors 231 and 233 are virtually short-circuited in this operation, because the signals at terminals 211 and 221 or 213 and 222 in the ideal case have the same frequency, amplitude, and phase.

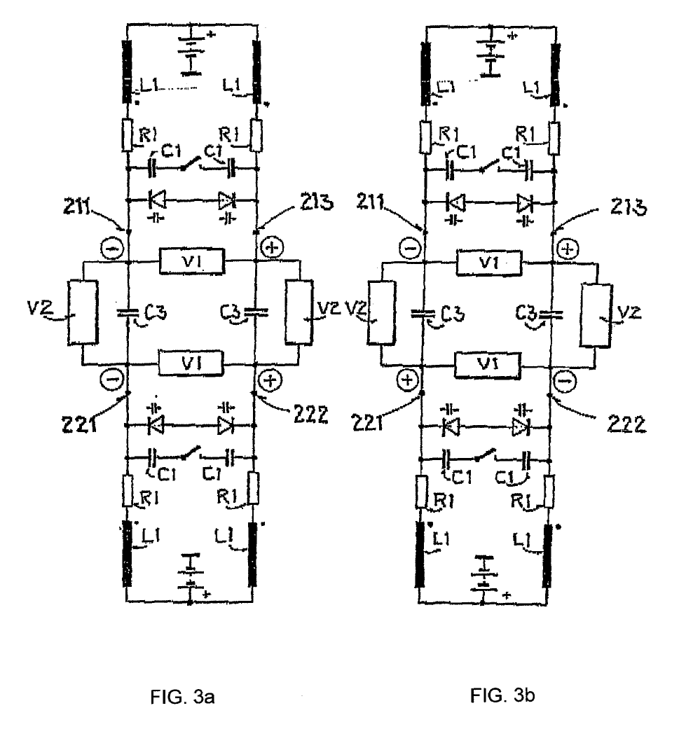

The different operating modes of the oscillator of FIG. 2 are shown in FIGS. 3a and 3b. FIG. 3a shows the polarity of the potentials applied at terminals 211, 213, 221, and 222 in the aforementioned first mode. As is also evident from FIG. 3a, terminals 211 and 221 or 213 and 222 each have the same potential (+ or −). The oscillation frequency in this mode is:

f=1/(2π\sqrt{L1C1}),

In the second mode shown in FIG. 3b, amplifiers 223 and 225 (V1) shown in FIG. 2 are turned off and amplifiers 227 and 229 (V2) turned on. The resulting potentials at terminals 211, 213, 221, and 222 are drawn in FIG. 3b. In this mode, capacitors 231 and 233 (C3) shown in FIG. 2 are no longer virtually short-circuited. Rather, the total amplitude is present across these capacitors. In this mode, only differential signals are amplified. The oscillation frequency in this mode is

f=1/(2π\sqrt{L1(C1+C3)})

It becomes clear from the above formula for the oscillation frequencies that the effective capacitance for the particular oscillation has changed between the two modes. The center frequencies of the bands can therefore be established by suitable selection of the capacitance values C3 of capacitors 231 and 233.

The quality of oscillation generating devices 201 and 203, shown in FIG. 2, each of which forms the tank circuit, corresponds to the quality of the two-circuit concept, shown in FIGS. 8a and 8b, because there is no major change in the total capacitance or total inductance.

In the case shown in FIG. 3a, capacitors 231 and 233 are moreover not reloaded. The oscillation in this mode can be, for example, 10 GHz. In the differential second mode from FIG. 3b, capacitors 231 and 233 are completely recharged, which causes a change in the oscillation frequency of the oscillator.

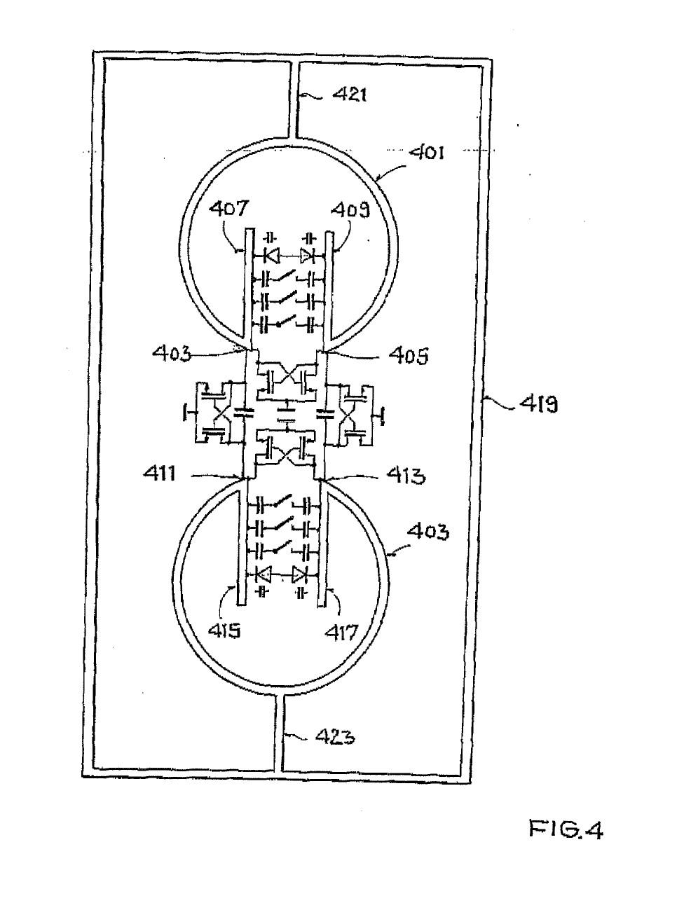

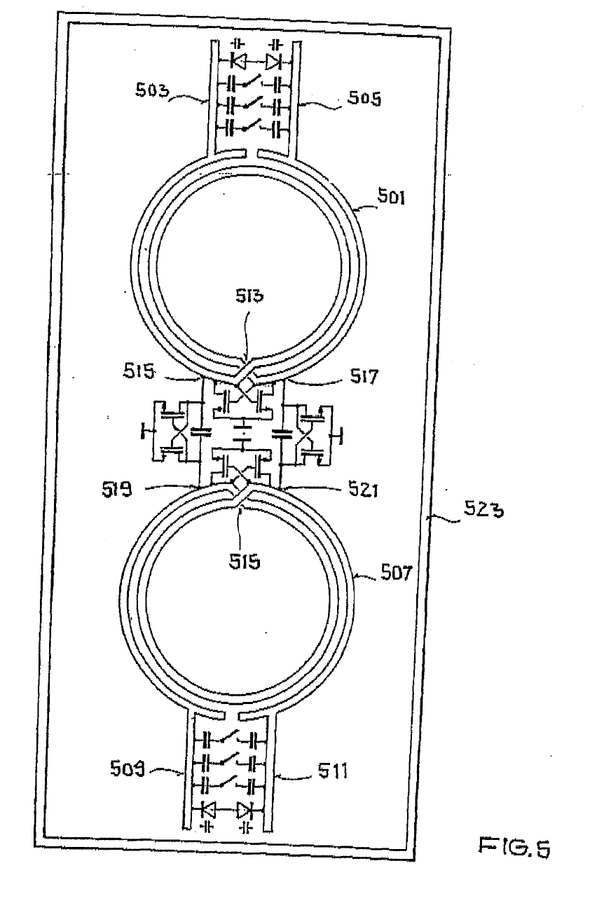

FIG. 4 shows an oscillator with a first oscillation generating device, a second oscillation generating device, and an excitation device. The first oscillation generating device comprises a conductive structure 401, which is formed substantially circular and forms an open loop. Conductive structure 401 comprises a first terminal 403, a second terminal 405, and a bent region 407 and 409.

The oscillation generating device also comprises a conductive structure 403, which forms an open, for example, a circular partial loop and has terminals 411 and 413. Conductive structure 403 comprises further a bent section 415, which is connected to terminal 411, and a section 417, which is connected to terminal 413.

A diode circuit with diodes connected in antiseries is provided between bent sections 407 and 409 of the first oscillation generating device. In addition, there is a plurality, for example, three, of capacitive networks, each with two capacitors connected in series via a switch between terminal 407 and terminal 409.

A capacitor is provided in each case between terminal 403 of the first oscillation generating device and terminal 411 of the second oscillation generating device and between terminal 405 of the first oscillation generating device and terminal 413 of the second oscillation generating device, the capacitors having, for example, identical capacitance values.

The excitation device comprises further four transistor amplifiers. A first transistor amplifier is disposed between first terminal 403 of the first oscillation generating device and third terminal 411 of the second oscillation generating device. The first amplifier comprises two coupled transistors, whose first terminals, for example, source terminals or drain terminals, are connected to one another, whereby a nodal point between these terminals is connected to ground, for example. The first transistor amplifier circuit is connected parallel to the capacitor disposed between terminals 403 and 411, whereby a second terminal of a first amplifier is connected to terminal 403 and a second terminal of a second transistor to terminal 411. The second terminals can be, for example, drain or source terminals.

The control terminal of the first transistor of the first transistor amplifier circuit is connected to the second terminal of the second transistor of the first transistor amplifier circuit. The control terminal of the second transistor of the first transistor amplifier circuit, in contrast, is connected to the second terminal of the first amplifier. The control terminals can be, for example, gate terminals.

A second transistor amplifier circuit is disposed between second terminal 405 of the first oscillation generating device and fourth terminal 413 of the second oscillation generating device. The second transistor amplifier circuit is identical to the first transistor amplifier circuit and disposed in an identical manner between terminals 405 of the first oscillation generating device and 413 of the second oscillation generating device.

A plurality, for example, three, of capacitive circuits, each comprising two capacitors connected in series via a switch, is disposed between the bent sections of conductive structure 403 of the second oscillation generating device. Further, a diode circuit comprising two diodes connected in antiseries is disposed between bent sections 415 and 417.

The oscillator shown in FIG. 4 comprises further another conductive structure 419, which can be, for example, rectangular or oval and encloses both the oscillation generating devices and the excitation device. The additional conductive structure 419 is preferably closed, whereby conductive structure 401 of the first oscillation generating device is connected with a conductive rib 421 to a front face of the additional conductive structure 419 and whereby conductive structure 403 of the second oscillation generating device is connected via a rib 423 to another front face of the additional conductive structure 419.

According to the invention, the conductive structures can be, for example, strip lines, microstrip lines, or metallized surfaces.

Based on the arrangement, shown in FIG. 4, of the conductive structures of the particular oscillation generating device, their respective bent sections 407, 409, as well as 415 and 417 are turned toward one another.

FIG. 5 shows an oscillator with an oscillation generating device, a second oscillation generating device, and an excitation device, which is coupled to the first and second oscillation generating device. The first oscillation generating device comprises a conductive structure 501, which is twisted, as shown in FIG. 5, and has bent sections 503 and 505, between which a plurality of capacitive circuits each with two capacitors connected in series via a switch and a diode circuit comprising two diodes connected in antiseries are disposed.

The second oscillation generating device comprises a conductive structure 507, which is also twisted and has the same form as conductive structure 501 of the first oscillation generating device. Conductive structure 507 of the second oscillation generating device comprises bent sections 509 and 511, between which a plurality of capacitive circuits each comprising two capacitors connected in series via a switch and a diode circuit comprising two diodes connected in antiseries are disposed.

Twisted regions 513 and 515 of the respective oscillation generating device 501 and 507 are turned toward one another.

Conductive structure 501 comprises a first terminal area 515 and a second terminal area 517. Conductive structure 507 of the second oscillation generating device comprises a third terminal area 519 and a fourth terminal area 521. Terminal areas 515 and 519 are connected to one another by means of a capacitor. In a similar way, terminal areas 517 and 521 are connected to one another by means of another capacitor. A first transistor amplifier circuit is connected parallel to the capacitors disposed between terminal areas 515 and 519. A second transistor amplifier circuit is disposed between terminal areas 515 and 517. A third transistor amplifier circuit is disposed between areas 517 and 521. A fourth transistor amplifier circuit is disposed between terminal areas 519 and 521. The transistor amplifier circuits form the excitation device and are preferably constructed exactly like the transistor amplifier circuits of the excitation device of FIG. 4.

As shown in FIG. 5, bent sections 503, 505, 509, and 511 are turned away from one another. The two oscillation generating devices and the excitation device are surrounded by a closed conductive structure 523, which can form a closed rectangular or circular or oval loop.

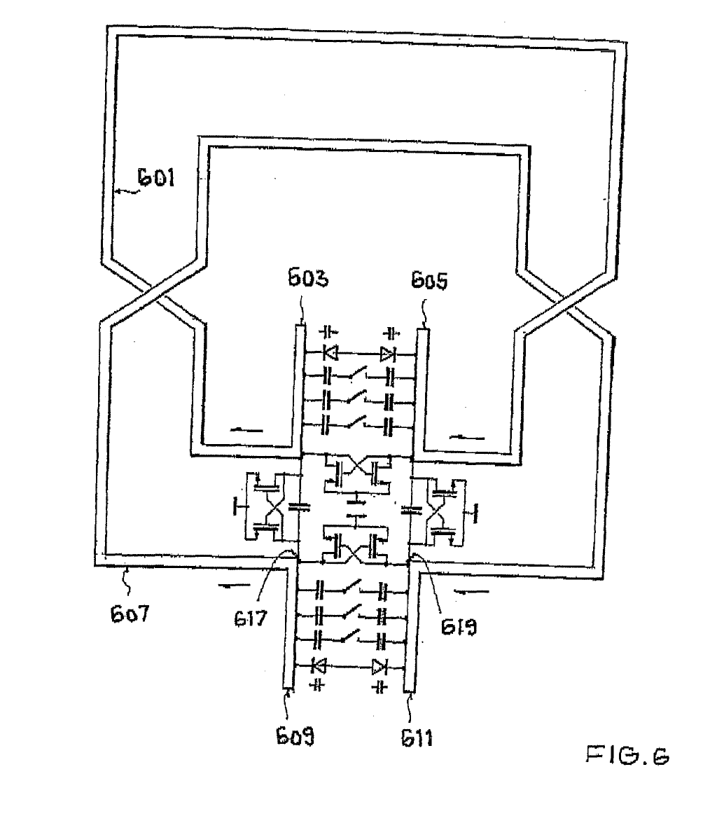

FIG. 6 shows an oscillator with a first oscillation generating device, a second oscillation generating device, and an excitation device.

The first oscillation generating device comprises a conductive structure 601, which forms an open loop, which becomes broader in the outward direction. First conductive structure 601 comprises bent sections 603 and 605, between which a plurality of capacitive circuits each comprising capacitors connected in series via a switch and a diode circuit comprising two diodes connected in antiseries are disposed.

The second oscillation generating device comprises a conductive structure 607, which encloses a region that becomes increasingly smaller in the outward direction and forms an open loop. Conductive structure 607 comprises conductive sections 609 and 611, between which a plurality of capacitive circuits each comprising two diodes connected in series via a switch and a diode circuit with two antiseries diodes are disposed.

Conductive structure 601 comprises a first region, which encloses a first area, and a second region, which encloses a second area, whereby the first region comprises bent sections 603 and 605 and whereby the second region extends outward from the first region. The second area is greater than the first area. In addition, bent sections 603 and 605 project into the first region.

Conductive structure 607 of the second oscillation generating device comprises a first region with a first area enclosed by said region and a second region with a second area enclosed by said region, whereby the first region merges into the second region. The first area enclosed by the first region is greater than that enclosed by the second region. In addition, bent sections 609 and 611 are bent outward.

Conductive structures 601 and 607 are disposed overlapping in such a way that the first region of conductive structure 601 of the first oscillation generating device encloses at least partially the first region of conductive structure 607 of the second oscillation generating device, and that the second region of conductive structure 607 of the second oscillation generating device encloses at least partially the first region of conductive structure 601 of the first oscillation generating device together with bent sections 603 and 605. Conductive structure 601 comprises terminal areas 613 and 615. In analogy thereto, conductive structure 607 of the second oscillation generating device comprises terminal areas 617 and 619.

The oscillator shown in FIG. 6 comprises further an excitation device, which is built precisely like the excitation device of FIGS. 4 and 5 and which is connected in the manner shown in FIG. 6 to terminal areas 613, 615, 617, and 619.

The total inductance can be influenced, furthermore, by the loop-shaped meshing of conductive structures 601 and 607, so that, for example, in a first overlapping a first total inductance and in a second overlapping a second total inductance are achieved that exert an effect on the oscillation frequency.

The capacitors and inductors shown in FIGS. 2 to 6 can be matched according to an embodiment to achieve a still greater variability in oscillation frequencies.

The topology shown in FIG. 4 is already notable for a reduced area requirement in comparison with the two-circuit concept, which does not permit a concentration of circuit elements, as shown in FIG. 4, because, e.g., of a guard ring.

Multiturn inductors are realized with the topology shown in FIG. 5 to achieve, for example, higher inductance values, which has an effect on the frequency of the resulting oscillation.

The topology shown in FIG. 6 is also notable for a high space efficiency. In addition, an inductive optimization of the oscillation amplitude between the two modes of the excitation device is achieved.

In this topology, in the first mode of the excitation device, a positive coupling results between the two inductors and in the second mode of the excitation device a negative coupling between the two inductors, each of which is realized by conductive sections 601 and 607, which may be, for example, microstrip lines, strip lines, or metallized area sections. A higher effective inductance is achieved in this way in the first mode and a lower effective inductance in the second mode. A very high space efficiency is achieved in the topology shown in FIG. 6, because the inductors, i.e., conductive structures 601 and 607, are integrated within one another. This overcomes the disadvantage that a large portion of the area requirement of a VCO (voltage-controlled oscillator) is occupied by the inductors. In addition, an amplitude optimization for both modes can be achieved, furthermore, with a combination of the two forms, i.e., the capacitive and inductive coupling.

According to an embodiment, the components of the respective oscillation generating device (tank circuit components) have, for example, the following values:

L1=200 pH, C1=1.2 pF, C3=1 pF.

The oscillation frequency f=10.3 GHz, for example, results for the first mode. The oscillation frequency f=6.2 GHz results for the second mode with the aforementioned values. The concept of the invention makes possible a higher frequency stability and improved phase noise caused by the double oscillation energy and/or synchronization of the oscillation generating devices. In addition, the performance is not worsened by the change in modes. The oscillator of the invention is notable for a lower space consumption and a higher loaded quality.

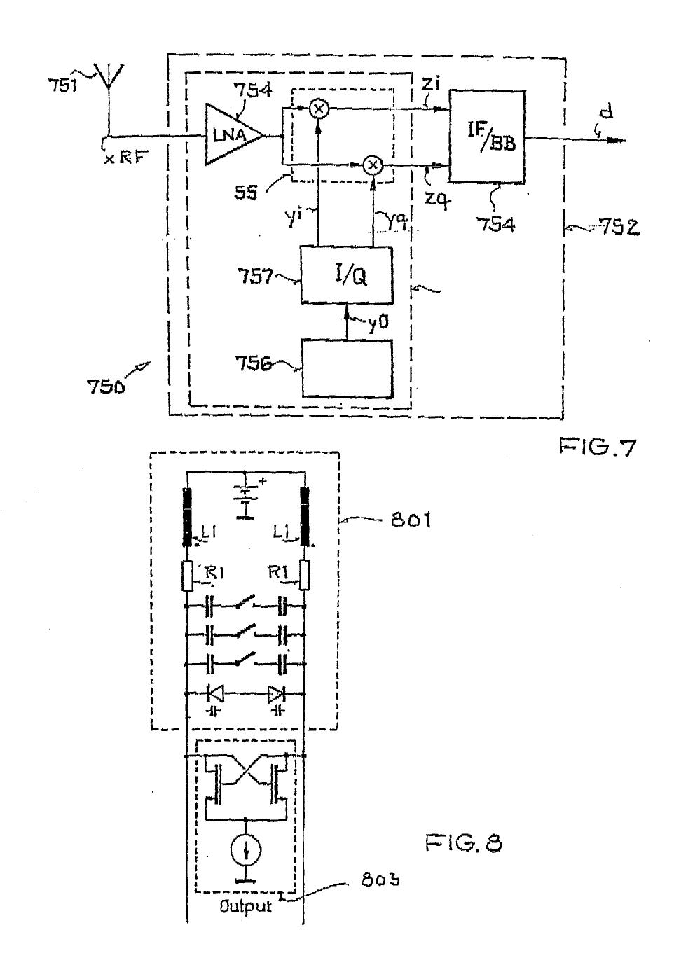

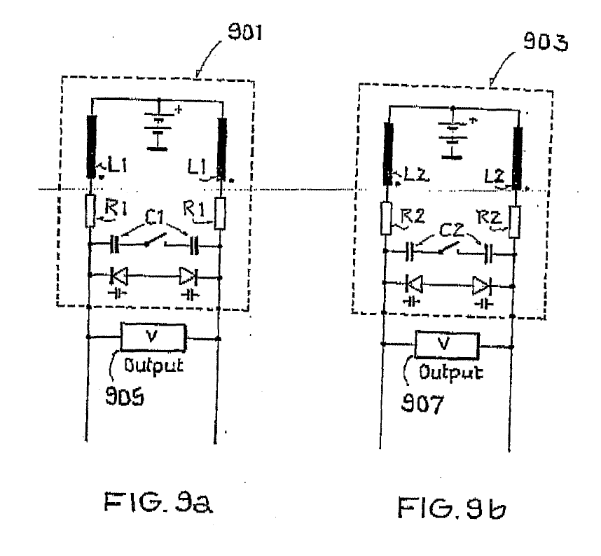

The oscillator of the invention can be used, for example, in a data transmission system according to IEEE 802.16 (WiMax, Worldwide Interoperability for Microwave Access). FIG. 7 shows a simplified block diagram of a transmitting/receiving device of an IEEE 802.16 system.

Transmitting/receiving device 750 has an antenna 751 and a transmitting/receiving unit (transceiver) 752 connected to the antenna. Transmitting/receiving unit 752 comprises an HF front-end circuit 753, connected to the antenna, and an IF/BB signal processing unit 754 connected downstream. Transmitting/receiving unit 752 furthermore comprises a transmission path, which is not shown in FIG. 7 and is connected to antenna 751.

HF front-end circuit 753 amplifies a high-frequency radio signal xRF, which is received by antenna 751 and lies spectrally within the microwave range between 3.4 and 3.6 GHz, and converts (transforms) it into a quadrature signal z in an intermediate frequency range (intermediate frequency, IF) or in the baseband range (zero IF). The quadrature signal z is a complex-valued signal with an inphase component zi and a quadrature phase component zq.

The IF/BB signal processing unit 754 filters the quadrature signal z and shifts it perhaps spectrally into the baseband, demodulates the baseband signal, and detects the data d contained therein and originally transmitted by another transmitting/receiving device.

The HF front-end circuit 753 has an amplifier (low noise amplifier, LNA) 754, connected to antenna 751, for amplifying the high-frequency radio signal xRF and a quadrature mixer 755, connected downstream, for converting the amplified signal into the quadrature signal z. Furthermore, the HF front-end circuit 753 has a circuit arrangement 756 and an I/Q generator 757, connected downstream and connected to quadrature mixer 755 on the output side.

Circuit arrangement 756 comprises a voltage-controlled oscillator (VCO) according to the invention, whose frequency is set relatively roughly with the use of control voltages vt1 and fine tuned with the use of other (optionally PLL-controlled) control voltages.

I/Q generator 757 derives from local oscillator signal y0 of circuit arrangement 756 a differential inphase signal yi and a differential quadrature phase signal yq phase-shifted by 90 degrees. Optionally, I/Q generator 57 comprises a frequency divider, amplifier elements, and/or a unit that assures that the phase offset of the signals yi and yq is 90 degrees as precisely as possible.

In other advantageous embodiments, the HF front-end circuit 753 has an amplifier (power amplifier), which is not shown in FIG. 7, in the transmission path.

The HF front-end circuit 753 and thereby the at least one circuit arrangement of the invention and perhaps parts of the IF/BB signal processing unit 754 are preferably a component of an integrated circuit (IC), which is formed, e.g., as a monolithic integrated circuit using standard technology, for example, in a BiCMOS technology, as a hybrid circuit (thin- or thick-layer technology), or as a multilayer ceramic circuit.

The circuit arrangement of the invention described heretofore by exemplary embodiments can be used advantageously in highly diverse applications, such as, e.g., in oscillator, amplifier, and filter circuits (settable transfer function, bandwidth, etc.).

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An oscillator comprising:
a first oscillation generating device generating an oscillation in response to an excitation signal, the first oscillation generating device having a first terminal and a second terminal;
a second oscillation generating device generating an oscillation in response to an excitation signal, the second oscillation generating device having a third terminal and a fourth terminal;
an excitation device, which, in a first mode, applies an excitation signal between the first terminal and the second terminal of the first oscillation generating device and applies the excitation signal between the third terminal and the fourth terminal of the second oscillation generating device to obtain a first oscillation with a first characteristic value, and, in a second mode applies an excitation signal between the first terminal of the first oscillation generating device and the third terminal of the second oscillation generating device and applies the excitation signal between the second terminal of the first oscillation generating device and the fourth terminal of the second oscillation generating device to obtain a second oscillation with a second characteristic value.

2. The oscillator according to claim 1, wherein the excitation device is formed in the first mode to apply no excitation signal between the first terminal and the third terminal, and wherein the excitation device is formed in the second mode to apply no signal between the second terminal and the fourth terminal.

3. The oscillator according to claim 1, wherein the first terminal of the first oscillation generating device is coupled to the third terminal of the second oscillation generating device via a capacitive or inductive network, and wherein the second terminal of the first oscillation generating device is coupled to the fourth terminal of the second oscillation generating device via a capacitive or inductive network.

4. The oscillator according to claim 1, wherein the excitation device has a first amplifier, which is connected between the first terminal and the second terminal of the first oscillation generating device, and has a second amplifier, which is connected between the first terminal of the first oscillation generating device and the third terminal of the second oscillation generating device.

5. The oscillator according to claim 1, wherein the excitation device comprises a third amplifier, which is connected between the third terminal and the fourth terminal of the second oscillation generating device, and a fourth amplifier, which is connected between the second terminal of the first oscillation generating device and the fourth terminal of the second oscillation generating device.

6. The oscillator according to claim 1, wherein the first oscillation generating device and the second oscillation generating device each have an inductive network with switchable capacitors.

7. The oscillator according to claim 1, wherein the first characteristic value and the second characteristic value are different.

8. The oscillator according to claim 1, wherein the first characteristic value or the second characteristic value is an oscillation amplitude or an oscillation frequency.

9. The oscillator according to claim 1, wherein the first oscillation generating device and the second oscillation generating device each have a conductive structure connected to one another conductively via another conductive structure.

10. The oscillator according to claim 1, wherein the first terminal and the second terminal of the first oscillation generating device are connected conductively via a conductive structure, and wherein the third terminal and the fourth terminal of the second oscillation generating device are connected conductively via a conductive structure.

11. The oscillator according to claim 1, wherein the first oscillation generating device and the second oscillation generating device each have a conductive structure, which is formed at least in part as a loop.

12. The oscillator according to claim 1, wherein the first oscillation generating device and the second oscillation generating device each have a conductive structure, which overlap at least in part.

13. The oscillator according to claim 1, wherein the oscillator is a reflection-type oscillator.

14. Use of an excitation device for oscillation generation, wherein the excitation device is formed in a first mode to apply an excitation signal between a first and a second terminal of a first oscillation generating device and between a third and fourth terminal of a second oscillation generating device to obtain a first oscillation with a first characteristic value, and wherein the excitation device is formed further in a second mode to apply an excitation signal between the first terminal of the first oscillation generating device and the third terminal of the second oscillation generating device and between the second terminal of the first oscillation generating device and the fourth terminal of the second oscillation generating device to obtain a second oscillation with a second characteristic value.

15. An oscillation generating method comprising:
generating an oscillation via a first oscillation generating device in response to an excitation signal, the first oscillation generating device having a first terminal and a second terminal;
generating an oscillation via a second oscillation generating device in response to an excitation signal, the second oscillation generating device having a third terminal and a fourth terminal;
applying, in a first mode, the excitation signal between the first and the second terminal of the first oscillation generating device and between the third and fourth terminal of the second oscillation generating device to obtain the first oscillation with a first characteristic value;
applying, in a second mode, the excitation signal between the first terminal of the first oscillation generating device and the third terminal of the second oscillation generating device and between the second terminal of the first oscillation generating device and the fourth terminal of the second oscillation generating device to obtain a second oscillation with a second characteristic value.
